(19) United States
(12) Patent Application Publication
(10) Pub. No.: US 2025/0359351 A1
(43) Pub. Date: Nov. 20, 2025

(54) COLORED SOLAR CELL COMPRISING EFFECT PIGMENTS

(71) Applicant: MERCK PATENT GmbH, Darmstadt (DE)

(72) Inventors: Marc HUNGER, Darmstadt (DE); Sebastian BARTH, Darmstadt (DE); Laurent DELOUX, Darmstadt (DE)

(73) Assignee: MERCK PATENT GmbH, Darmstadt (DE)

(21) Appl. No.: 18/854,269

(22) PCT Filed: Apr. 5, 2023
(86) PCT No.: PCT/EP2023/058908

§ 371 Date: Oct. 4, 2024

(30) Foreign Application Priority Data
Apr. 8, 2022 (EP) 22167282.7

(51) Int. Cl. H10F 19/80; H10F 19/85; H10F 77/42

(52) U.S. Cl. CPC H10F 19/804; H10F 19/807; H10F 19/85; H10F 77/42

(57) ABSTRACT

A colored solar cell or colored solar cell module comprising two or more transparent front cover layers each comprising an effect pigment of different color, and a process for its preparation.

### CROSS-REFERENCE TO RELATED APPLICATIONS

This application is a U.S. national stage application filed and claiming priority under 35 U.S.C. §§ 120 and 365(a) of International Application No. PCT/EP2023/058908, filed Apr. 5, 2023, and claiming priority under 35 U.S.C. § 119 of and to European Patent Application No. 22167282.7, filed Apr. 8, 2022, each of which applications is incorporated herein by reference in its entirety and for all purposes.

### BACKGROUND OF THE INVENTION

The invention relates to a colored solar cell or colored solar cell module comprising two or more transparent front cover layers each comprising an effect pigment of different color, and to a process for its preparation.

Solar cells have shown a great success over the last years and have surpassed the global grid-connected installation of 600 GW in 2019 with the majority being installed in utility scale. The basic function of all solar cells relies upon a photoactive material that absorbs light and generates an excited electron-hole pair. This electron-hole pair is separated within the solar cell by areas with different mobilities for electrons and holes, so called p-n junctions. As different kinds of light absorbing materials can be used, in the solar industry different kinds of solar cell technologies are known:
1) Crystalline silicon solar cells (mono crystalline c-Si and multi crystalline mc-Si)
2) Cadmium-Telluride Solar cells (CdTe)
3) Copper-Indium-Gallium-Diselenide (CIGS/CIS)
4) Amorphous silicon solar cells (a-Si)
5) III/V solar cells like Gallium-Arsenide (GaAs) solar cells or multi-junction solar cells consisting of stacks of group III and group V elements like Germanium/Indium-(Aluminium)-Gallium-Arsenide or phosphide (In(Al)GaAs/P)
6) Dye sensitized solar cells (DSSC)
7) Organic solar cells (OSC)
8) Perovskite solar cells (PSC)
9) Quantum dot solar cells (QSC)
10) Other II/VI solar cells consisting of elements of group II and group VI like Zinkselenide (ZnSe) or Ironsulfide (FeS)
11) Tandem solar cells

Nevertheless, using more surfaces e.g. of buildings and other surfaces on objects (e.g. cars) would increase the overall surface area which could be used for solar energy production. For this purpose, new techniques and approaches to make solar cells with appealing colors and color shades and to increase efficiencies under different angles of incidence are of major interest for the solar energy business.

A good color impression can be achieved for example by using a rear encapsulant film with the same color as the solar cells and with coloring the conducting parts of the solar module/panel. However, for every installation of a building a customized color may be requested by the market or the building owner. This makes the coloration complex and costly.

WO 2019/122079 A1 discloses colored solar cells or solar cell modules comprising a layer containing semi-transparent effect pigments. The semi-transparent effect pigments control the color of the light-incident surface side without impairing the efficiency of the solar panels. The effect pigments are reflecting a part of the visible sunlight, but let pass the light needed to create energy. Since the effect pigments are platelet-shaped, their color reflection will decrease the more the pigment platelets are oriented such that their edges are facing the visual surface of a solar module. Therefore the effect pigments should preferably be oriented predominantly substantially parallel to the module surface, while a certain random orientation to some extent may still be desirable to maintain a viewing angle related color impression. The color can be implemented by using a single pigment or a mixture of pigments e.g. in a glass color applied and cured on the front glass or e.g. by extruding a single pigment or mixture of pigments into an encapsulant polymer film and use the colored polymer film as front encapsulant in a solar module or device.

In order to customize the color, mixing and application of a glass color can be done efficiently for a small batch size. However, an additional printing and curing step is needed which is a cost disadvantage. Also, when using pigment mixtures in a large scale process of manufacturing colored solar cells, the color may slightly vary from batch to batch so that reproduction of the same color for modules covering a large area may be difficult.

### SUMMARY OF THE INVENTION

It is therefore an object of the present invention to provide an improved method for coloring solar cells and solar cell modules, which does not have the drawbacks observed in prior art methods, which does enable coloring solar cells in a broad range of customized colors, which provides solar cell modules with uniform color appearance even over large areas, and which are suitable for a large scale production process that is time- and cost-effective.

Another object of the present invention is to provide improved colored solar cells and solar cell modules which have uniform color appearance over a wide range of customized colors. Another object of the present invention is to provide a method enabling to increase the flexibility in creating customized colors and using colored encapsulant films for solar cells and solar cell modules. Further objects of the invention are immediately evident to the skilled person from the following description and examples.

It was surprisingly found that one or more of these objects could be achieved by colored solar cells and solar cell modules as disclosed and claimed hereinafter, which comprise two or more different transparent front cover layers, wherein each transparent front cover layer (hereinafter also abbreviated as “TFCL”) contains an effect pigment of different color.

The present application relates to a colored solar cell or colored solar cell module comprising two or more TFCLs, each of said TFCLs containing at least one, preferably only one, effect pigment that has a specific color and consists of a transparent or semi-transparent flake-form substrate coated with one or more layers of transparent or semi-transparent materials and optionally a post coating, and wherein at least one of the TFCLs contains an effect pigment having a different color than the effect pigment(s) contained in the other transparent front cover other layer(s).

Preferably the TFCLs are encapsulant layers or films or a component thereof, or form together a front encapsulant film or a component thereof.

The application further relates to a process of preparing a colored solar cell or colored solar cell module comprising the steps of laminating two or more TFCLs, each of which contains an effect pigment as described above and below having a specific color, to the front side of a solar cell or a solar cell module, wherein at least one of the TFCLs contains an effect pigment having a different color than the effect pigment(s) contained in the other TFCL(s).

The invention further relates to the use of the colored solar cells and colored solar cell modules as described above and below in an architectural installation or a device preferably selected from windows, doors, building façades, building roofs or floors, walls, structural glass, curtain walls, showrooms, car roofs, car bodies, mobile phones, hand-held PC's such as tablets, plug-in solar modules, roof tiles, solar panels, photovoltaic (PV) fences, military devices, radio sets, radio equipment, music boxes, power banks, watches, eyeglasses and goggles.

The invention further relates to an architectural installation or a device comprising one or more colored solar cells or colored solar cell modules as described above and below, said installation or device preferably selected from windows, doors, building façades, building roofs or floors, walls, structural glass, curtain walls, showrooms, car roofs, car bodies, mobile phones, hand-held PC's such as tablets, plug-in solar modules, roof tiles, solar panels, PV fences, military devices, radio sets, radio equipment, music boxes, power banks, watches, eyeglasses and goggles.

Above and below, the term “front side” of the solar cell or solar cell module means the light-receiving side or the side facing incident light, and the term “rear side” or “back side” of the solar cell or solar cell module means the side opposite to the radiation-receiving side or facing away from incident light. The terms “front cover layer” or “front encapsulant film” mean a layer, sheet or encapsulant film provided on the front side of the solar cell or solar cell module. The terms “rear glass/sheet” and “rear encapsulant film” mean the glass, sheet or encapsulant film provided on the rear side of the solar cell or solar cell module.

Above and below, unless stated otherwise the term “solar cell” is understood to encompass both single solar cells and solar cell modules, as well as arrays, strings or patterns of the aforementioned. Likewise the term “solar cell modules” is understood to encompass also single solar cells unless stated otherwise.

Above and below, unless stated otherwise weight percentages of the light scattering particles and effect pigments are based on the total weight of the solid part of the layer, sheet or film.

Above and below, a layer, sheet or film according to the invention is also briefly referred to as “layer”, which is understood to be inclusive of a layer, sheet or film according to the invention as described above or below.

### BRIEF DESCRIPTION OF THE DRAWING FIGURES

FIG. 1 is a schematic illustration of a colored solar cell module according to the present invention.

### DETAILED DESCRIPTION OF THE INVENTION

The present invention offers a highly efficient method of coloring state of the art solar cells, or solar cell modules made of a plurality of electrically interconnected solar cells, with great flexibility and achieving a wide range of different colors with a low or negligible loss in solar cell efficiency, and a high level of long term stability. Additionally, the invention provides a solution to achieve a wide variety of customized colors with good batch-to-batch reproducibility and suitability for wide area applications.

Thus, it was surprisingly found that, by applying two or more single TFCLs, for example as front encapsulant, wherein each of said layers contains an effect pigment of a different individual color, as a stack of films in the lamination process of a solar module, a wide range of customized colors can be created.

For example, when using a stack of two or more of Red/Green/Blue colored encapsulant polymer films which are laminated onto a solar cell, it was surprisingly found that after lamination an uniform grey color can be achieved which shows a color appearance similar to a single encapsulant polymer film containing the corresponding mixture of Red/Green/Blue pigments which had been added to the polymer melt and extruded with the polymer film. However, an encapsulant film containing only one type of color effect pigment with a constant color appearance is easier to reproduce in a large batch than a film containing a mixture of effect pigments having different colors. Therefore, by simply laminating the different colored films on the solar cell module a wide range of customized colors can more easily be reproduced and batch-to-batch color variation can more easily be suppressed.

The method according to the present invention also enables to create different colors at the process step of solar cell module lamination instead of the process step of film extrusion. Also, when using multiple colored encapsulant films there is no need for an additional production step. Instead, the solar module manufacturer only has to replace the non-colored encapsulant film by two or more colored encapsulant films or by a multilayer of the two or more colored encapsulant films.

Moreover, as the cost-efficient production of a colored film usually requires a large batch size of several tons, it is more efficient to produce multiple colored films of different color, which can be stored and, upon an individual request from the solar cell module manufacturer, then be combined in any fashion to produce the desired color, instead of producing a colored film with a specific pigment mixture in large scale upon each individual request.

The use of two or more effect pigment-containing layers renders the appearance of the solar cell front surface to different colors obtained by mixing base colors like red, green, blue etc. With this method a solar module manufacturer can thus easily create a wide range of colors e.g. just out of three basic films with the colors Red, Green and Blue on hand. There is no need to produce every color with a single production run of film extrusion. This solves the problem to simplify color creation with colored encapsulant films and to get around the limitations of single batch size production. Thus, a relatively large standard batch size is usually needed for the production of a colored encapsulant film to achieve constant color and film quality. This batch size is much larger than the single batch size for an encapsulant film required e.g. for covering the solar cell modules of a standard building in an individual project. Therefore, with a standard size batch of a colored encapsulant film, or a set of films, of a customized color it is possible to serve multiple individual project requests, making the production of colored encapsulant films more time- and cost-effective.

The method according to the present invention thus makes it easier to adjust colors because different colors can be achieved simply by combining colored standard films instead of having to produce a film for each color.

For example, a turquoise color can be produced with layers of green and blue pigments, a yellow color can be produced with layers of red and green pigments, and a pink color can be achieved by layers of red and blue pigments.

The effect pigments as used in the present invention provide a color by light reflection and not by light absorption as conventional dyes and pigments. Effect pigments in Red, Green and Blue can be selected to have similar transmission properties for light, with the transmission values typically all being >80%. This makes it easier to crate verity colors with a transmission value >80% even for a color like grey. This another advantage of using combination of RGB films.

Apart from selecting the reflection colors of the effect pigments in the individual TFCLs, the color combination can be further varied by altering the thickness of the individual layers and/or by altering the concentration of the effect pigment in the individual layers and/or by altering the number of individual layers of the same or different colors, for example by combining one or more first TFCL(s) of a first color with one, two or more second TFCLs of a second color and optionally with further TFCLs of further colors.

In addition, by uni- or biaxially stretching or drawing the front cover film to a certain extent before or during the lamination of the solar module, a changing color effect over the surface can be achieved in order to create marble like effects or patterns and structures. This is especially useful when decorating buildings where different color structures are required.

In a preferred embodiment of the present invention, the colored solar cell or colored solar cell module comprises two or more, preferably two to six, very preferably two, three, four or five, most preferably two or three, TFCLs, at least one of which, preferably each of which contains an effect pigment having a color that is different from the color of the effect pigments in the other TFCLs.

In another preferred embodiment of the present invention, the colored solar cell or colored solar cell module comprises two or more, preferably two, three, four or five TFCLs at least one of which, preferably each of which contains an effect pigment that has a different color than the effect pigments contained in the other TFCLs and is selected from silver white, yellow, red, green and blue effect pigments, respectively.

As the effect pigments show a characteristic color by light reflection, the color effect is visible especially against a dark or black background. Therefore, preferably the colored solar cell or colored solar cell module according to the present invention comprises a black or dark colored (e.g. dark blue) rear sheet, for example a black or dark colored rear encapsulant sheet or film.

For a typical application the concentration of the effect pigments in the TFCL should preferably be ≥1 g/m² as otherwise the solar cell structure could be still visible while the color impression can already be strong. In addition to the higher hiding power, the angle dependency of the color of the solar cell module is reduced. The combination of two or more base colors like red, green and/or blue opens up new possibilities of designing colored solar cell modules of an individual, customized color selected from a wide variety.

It has been also found that a stack of TFCLs, each of which contains an effect pigment of different color, is ideal to provide sufficient color without significantly reducing the overall solar cell efficiency. Long term tests showed a high level of stability. As the direct contact between the effect pigment-containing layer and the solar cell is the most demanding location in the setup of the solar module, it can safely be assumed that the effect pigment-containing layer will also not show negative influence if used in any other position of the solar module stack.

The effect pigments are reflecting a part of the incident visible light, but are letting pass the light needed to create energy by the photovoltaic process. The effect pigments can be oriented such that it is possible to modify the angle of best efficiency and thus to play with color and efficiency.

The layers with the effect pigments can easily be applied to state of the art solar cells, making their application even more efficient. The process steps of applying the layers containing the effect pigment to the solar cell module can easily be integrated into existing state of the art processes for manufacturing encapsulated solar cell modules.

By use of the present invention, the visual appearance of solar cells can be adapted to special needs. The exterior visual appearance of objects comprising solar cells such as buildings, devices, automotive vehicles, etc. can be improved and transparency and reflectivity of the solar cells can be controlled. Furthermore, visibility of the cells and the bright colored bus bars can be reduced or even avoided when a dark back sheet is used and the bus bars and connection points are darkened. Also, the invention can be used to provide solar cells with extraordinary colors to achieve special effects and designs, for example depending on the used effect pigment also a texture can be added such as e.g. a sparkle effect on the panels, mimicking brick walls or color shaded of different surfaces of material used in construction of houses.

Another advantage of the present invention is the possibility to seamlessly integrate solar cells into any surface by changing its appearance to a neutral look which people are used to many, for example into the surface of buildings (façade and roof), hand held, portable and installed devices, automotive vehicles or other transportation objects (cars, trucks, motorcycles, scooters, trains, ships, trailers etc.), price tags, plastics, wearable items and home appliances or similar, or any other highly visible surface that needs a seamless integration of solar cells without changing its optical appearance, or other kinds of solar installations, where the typical technical appearance of solar cells would change to a neutral look which people are used to, and where long-term stability is essential.

Additionally, the costs of solar power are not increased in a significant way, because the efficiency of the colored solar cell is not impacted too heavily in contrast to currently available technologies, which have the great drawback of an impact on the solar cell performance and where under real life conditions the efficiency of the solar cell may drop below 10% from an initial performance of >15%.

The coloration of solar cells according to the present invention is possible over a wide variety of colors and not limited to a rigid substrate like glass or a single solar cell technology.

The effect pigments in the TFCL according to the present invention are preferably selected from pearlescent pigments, interference pigments and multilayer pigments.

In a preferred embodiment of the present invention, the effect pigments are selected from interference pigments. The optical effect of interference pigments is based on the difference in the refractive index of the materials which are arranged one on top of the other in the pigments in the form of thin layers and reflect, transmit and possibly also absorb incident light differently depending on the refractive index of the respective layer and of the medium surrounding the interference pigment. Refractive index differences between adjacent layers cause path differences in the reflected light rays, so that they interfere with one another and light of certain wavelengths is amplified or weakened wavelength-selectively. The reflected light rays in the visible wavelength region amplified in this way are perceived by the observer as a visible interference color under suitable conditions. If all layers of the interference pigments are composed of transparent, colorless materials, only interference colors, but no mass tones, of the interference pigments are perceptible.

Optically, the interference colors of the interference pigments which do not have absorption colors act like colored light rays, i.e. combine additively with one another. Thus, e.g. a stack of three TFCLs each comprising a different interference pigment selected from Red, Green and Blue interference pigments (i.e. interference pigments which exhibit a Red, Green or Blue interference color in the application medium) will give a grey or whitish color hue.

Individual interference pigments generally consist of a flake-form support material and one or more layers which are more or less transparent, with which the flake-form supports are coated. However, the uniform layer thickness of the support and of the individual layers, the homogeneity of the composition of the individual layers and the surface nature of support and individual layers as well as the size and size distribution of the pigments determine, inter alia, the extent to which the optical behaviour of the respective interference pigments differs from the ideal behaviour of the materials currently employed.

The preparation conditions of interference pigments thus can have a major influence on their optical behaviour. Therefore differences in the optical behaviour, expressed by, for example, saturation, lightness or color angle, may be observed for interference pigments which formally have the same hue (for example red) and formally have the same layer structure (for example titanium dioxide layer on mica flakes), depending on the manufacturer and the preparation process employed, and even depending on the respective batch. However, these drawbacks can be overcome by using a method according to the present invention, which enables the creation a wide range of colors using e.g. three basic films with the colors Red, Green and Blue, without the need to create every individual color in a single film production process, and thereby circumventing the limitations of single batch production.

The effect pigments are preferably based on synthetic or natural mica, flake-form glass substrates, flake-form SiO₂ substrates or flake-form Al₂O₃ substrates. The flake-form substrate is preferably coated with one or more layers of metal oxides and/or metal oxide hydrates of Ti, Sn, Si, Al, Zr, Fe, Cr and Zn.

The effect pigments used in the TFCL in accordance with the present invention are preferably transparent or at least semi-transparent. The effect pigments useful for the invention exhibit preferably a yellow, red, blue or green color. However, other colors like grey, white, violet, red or orange are also suitable. Other colors or their mixture to produce specific colors and shades can also be used. The effect pigments can also produce metallic effects, such as but not limited to: silver, platinum, gold, copper and variety of other metals.

In a preferred embodiment of the present invention, each individual TFCL contains only one type of effect pigment.

The effect pigments preferably comprise, and very preferably consist of, a transparent or semi-transparent flake-form substrate coated with one or more layers of transparent or semi-transparent materials and optionally a post coating

Preferably the effect pigments contain a flake-form substrate which comprises at least one coating comprising a metal oxide, metal oxide hydrate or mixtures thereof. Preferably, the effect pigments consist of transparent or semi-transparent, colorless, flake-form substrates, which have been coated with one or more layers of transparent or semi-transparent, colorless materials. Preference is given to the use of pearlescent pigments, interference pigments, and/or mutlilayer pigments. Long term stability of the effect pigments can preferably be improved with using a post coating of organic coatings and/or inorganic coatings as last layers of the effect pigments as described for example in WO 2011/095326 A1 and below.

Suitable substrates for the effect pigments are, for example, all known coated or uncoated, flake-form substrates, preferably transparent or semi-transparent, preferably colorless flakes. Suitable are, for example, phyllosilicates, in particular synthetic or natural mica, glass flakes, SiO₂ flakes, Al₂O₃ flakes, TiO₂ flakes, liquid crystal polymers (LCPs), holographic pigments, BiOCl flakes or mixtures of the said flakes. Aluminum flakes with dielectric coatings can also be used according to the invention at low concentrations to obtain a very high hiding power of the active photovoltaic layer.

The glass flakes can consist of all glass types known to the person skilled in the art, for example of A glass, E glass, C glass, ECR glass, recycled glass, window glass, borosilicate glass, Duran® glass, labware glass or optical glass. The refractive index of the glass flakes is preferably 1.45 to 1.80, in particular 1.50-1.70. Especially preferred glass flakes consist of A glass, C glass, E glass, ECR glass, quartz glass and borosilicate glass.

Preference is given to coated or uncoated flakes of synthetic or natural mica, SiO₂ flakes, Al₂O₃ flakes, and glass flakes, in particular glass flakes of C glass, ECR glass or calcium aluminum borosilicate. Especially, effect pigments based on calcium aluminum borosilicate glass are preferably used. In a variant of the invention Al₂O₃ flakes are preferred.

The substrates generally have a thickness of between 0.01 and 5 μm, in particular between 0.05 and 4.5 μm and particularly preferably from 0.1 to 1 μm. The length or width dimension is usually from 1 to 500 μm, preferably from 1 to 200 μm and in particular from 5 to 125 μm. They generally have an aspect ratio (ratio of mean diameter to mean particle thickness) of from 2:1 to 25,000:1, preferably from 3:1 to 1000:1 and in particular from 6:1 to 250:1. The said dimensions for the flake-form substrates in principle also apply to the coated effect pigments used in accordance with the invention, since the additional coatings are generally in the region of only a few hundred nanometers and thus do not significantly influence the thickness or length or width (particle size) of the effect pigments.

The particle size and the particle size distribution of the effect pigments and their substrates can be determined by various methods usual in the art. However, use is preferably made of the laser diffraction method in a standard process by means of a Malvern Mastersizer 2000, Beckman Coulter, Microtrac, etc. In addition, other technologies such as SEM (scanning electron microscope) images can be used.

In a preferred embodiment, the substrate is coated with one or more transparent or semitransparent layers comprising metal oxides, metal oxide hydrates, metal hydroxides, metal suboxides, metal fluorides, metal nitrides, metal oxynitrides or mixtures of these materials. Preferably, the substrate is partially or totally encased with these layers.

Furthermore, effect pigments with multilayered structures comprising high- and low-refractive-index layers may also be used, where high- and low-refractive-index layers preferably alternate. Particular preference is given to layer packages comprising a high-refractive-index layer (refractive index ≥2.0) and a low-refractive-index layer (refractive index <1.8), where one or more of these layer packages may have been applied to the substrate. The sequence of the high- and low-refractive-index layers in the effect pigments can be matched to the pigment substrate here in order to include the pigment substrate in the multilayered pigment structure.

Particular preference is given to metal oxides, metal oxide hydrates or mixtures thereof, preferably of Ti, Sn, Si, Al, Zr, Fe, Cr and Zn, especially of Ti, Sn and Si. Oxides and/or oxide hydrates may be present in a single layer or in separate layers.

Particularly, titanium dioxide, in the rutile or anatase modification, preferably in the rutile modification is used. For conversion of titanium dioxide into the rutile modification, a tin dioxide layer is preferably applied beneath a titanium dioxide layer. Preferred mutlilayer coatings comprise alternating high- and low-refractive-index layers, preferably such as TiO₂—SiO₂—TiO₂.

The layers of metal oxides, hydroxide and/or oxide hydrates are preferably applied by known wet-chemical methods, where the wet-chemical coating methods developed for the preparation of effect pigments, which result in enveloping of the substrate, can be used. After the wet-chemical application, the coated products are subsequently separated off, washed, dried and preferably calcined.

The thickness of the individual layers in the effect pigment is usually 10 to 1000 nm, preferably 15 to 800 nm, in particular 20 to 600 nm, especially 20 to 200 nm.

In order to increase the light, temperature, water and weather stability, the effect pigment may be subjected to post-coating or post-treatment. The post coating may be an organic coating and/or an inorganic coating as last layer/s. Post coatings preferably comprising one or more metal oxide layers of the elements Al, Si, Zr, Ce; Fe, Cr or mixtures or mixed phases thereof. Furthermore, organic or combined organic/inorganic post-coatings are possible. Silanes and/or organofunctional silanes may also be used, alone or in combination with metal oxides. Suitable post-coating or post-treatment methods are, for example, the methods described in DE 22 15 191, DE-A 31 51 354, DE-A 32 35 017 or DE-A 33 34 598, EP 0090259, EP 0 634 459, WO 99/57204, WO 96/32446, WO 99/57204, U.S. Pat. Nos. 5,759,255, 5,571,851, WO 01/92425, WO 2011/095326 or other methods known to the person skilled in the art man.

Effect pigments which can be used for the invention are, for example, the commercially available interference pigments or pearlescent pigments offered under the trade names Iriodin®, Pyrisma®, Xirallic®, Miraval®, Colorstream®, Spectraval®, RonaStar®, Biflair®, and Lumina Royal®. Other commercially available effect pigments may also be used. Especially, Colorstream®, Xirallic®, Miraval®, and Ronastar®, Pyrisma® pigments may be used.

An individual TFCL according to the present invention may also comprise a mixture of two or more, preferably three or more different effect pigments, very preferably a mixture of one or more of Silver White, Yellow, Red, Green and Blue effect pigments. Depending on the concentrations of the individual effect pigments an even wider color space/range can thereby be achieved and further special effects can be obtained. In this preferred embodiment the effect pigments can be mixed in any proportion, but preferably the overall content of all effect pigments in one TFCL should not exceed 40% by weight, more preferably 10% by weight.

In a preferred embodiment, however, each individual TFCL according to the present invention does only contain an effect pigment of one color, preferably selected from the group consisting of Silver White, Yellow, Red, Green and Blue.

The concentration of the effect pigments in an individual TFCL according to the present invention is preferably from 0.01 to 20%, very preferably 0.02 to 15% by weight. More preferably, the concentration of the effect pigments in an individual TFCL according to the present invention is from 0.05 to 10% by weight, even more preferably 0.1 to 5%, most preferably 0.1 to 1% by weight.

In another preferred embodiment the amount of effect pigment per m² of an individual TFCL according to the invention is in the range of 0.1 g/m² to 75 g/m², more preferably in the range of 0.2 to 30 g/m², very preferably 0.5 to 15 g/m², most preferably 0.5 to 6 g/m².

The TFCL may in addition to the effect pigment also comprise one or more additives. For example, in may comprise one or more light scattering centers or light scattering particles, which provide a haze in the pigment containing layer that advantageously reduces the appearance of dark patterns in the shape of the solar cell array structure or the electrical interconnects bus bars etc., but does on the other hand not significantly reduce the transmission of the pigment containing layer, and does thus not negatively affect the power conversion efficiency of the solar cell. Suitable and preferred light scattering centers and particles are disclosed for example in CN113809194A.

In a preferred embodiment the TFCL contains one or more light scattering particles selected from silica spheres or flour, spherical silicone resin powder, BaSO₄, Al₂O₃, BaMgAlOₓ or Eu-doped BaMgAlOₓ particles or glass bubbles, preferably at a concentration of 0.001 to 10%, more preferably 0.005 to 10%, even more preferably 0.005 to 5%, very preferably 0.005 to 3%, most preferably 0.01 to 1.5% by weight, and further preferably 0.1 to 10 g/m².

The TFCLs according to the present invention containing the effect pigments are preferably selected from polymer films or sheets.

Preferred polymer films are selected from polyolefin polymers or copolymers, in particular polyethylene polymers or copolymers, including but not limited to polyethylene, EVA (ethylene vinyl acetate), EBA (ethylene butyl acrylate), EMA (ethylene methyl acrylate), EEA (ethylene ethyl acrylate), POE (polyolefin elastomer), BPO (polyolefin copolymer), furthermore PVB or TPU (thermoplastic polyurethane), preferably EVA or polyethylene copolymers.

In another preferred embodiment the front transparent cover layers are polymer films or sheets that are incorporated into a solar cell module or an architectural glass façade.

The thickness of an individual TFCL containing the effect pigment is preferably in the range of 5 μm to 1000 μm, more preferably 20 μm to 800 μm, even more preferably 100 μm to 300 μm.

The effect pigments and optional additives like the light scattering particles can be incorporated into the TFCLs according to the invention by methods known to the skilled person and described in the literature.

If the TFCL according to the present invention is a polymer film, it can prepared by for example by extrusion methods such as melt extrusion of a polymer material wherein the effect pigment(s) and optional additives are added to the polymer melt before extrusion.

In extrusion, thermoplastics are melted to a viscous mass in a screw and then pressed into shape through a flat film die. The variety of possible shapes is huge. Films, foils, and plates are extruded through flat dies.

Finally, the polymer film is typically structured, for example embossed, over a heated and structured roll in order to enable a better venting of air during the solar module lamination process. According to the invention one or more layers of the multilayer stack can be structured. The structurization or embossing of each individual film can improve the orientation of the effect pigments in the film-especially for very thin films- and can thus also be used to individually adopt the appearance of the TFCL film stack.

Masterbatches or compounds are usually used to color the molten mass with effect pigments and optional additives. For a satisfactory result in plastic extrusion with effect pigments and optional additives, a balanced ratio must be maintained between the mixture energy and effect pigments and/or additives that are as undamaged as possible. Excessive shear from mixing sections or inappropriate screws or filters destroy effect pigments and dramatically decrease the pearl luster effect. The orientation of the pigments is critical for an even effect. This has to be ensured in the process through corresponding engineering and design of the machinery.

In a preferred embodiment of the present invention a masterbatch comprising the desired amount, e.g. 5 to 30% by weight, of the effect pigments and optional additives in the polymer material is added during the extrusion process of the polymer film. This can be done for example by creating a premix of the colored masterbatch pellets with the EVA pellets, or by any other known methods.

Due to the shear forces acting upon the effect pigments during the melt extrusion process the effect pigments are oriented substantially parallel to the encapsulant film surface.

In another preferred embodiment, the TFCL containing the effect pigment(s) and scattering particle(s) is a co-extruded film of two or more layers of the same or different polymer materials wherein at least one layer, preferably the layer facing the front sheet, contains one or more effect pigments.

In another preferred embodiment the two or more TFCLs are compressed at heat, optionally together with further front layers, to form a fused multilayer stack.

EVA, employed as an encapsulant for the lamination of PV modules, is a thermoplastic polymer of which the formulation is especially adapted for use in solar applications. It brings high electrical insulation, transparency, flexibility and softness. In cross-linked formulations (like for encapsulants), it exhibits additionally high dimensional stability, fast curing and easy lamination. Common EVA formulations typically comprise, besides the polymer resin, a crosslinking agent, an adhesion promoter, a UV absorber, a UV stabilizer, and antioxidant agents. The crosslinking agent is a radical initiator-usually a peroxide-which decomposes under heat during the lamination and will form free radicals that initiate radicals on the polymeric backbone. The formed radicals will in turn lead to the formation of covalent bonds between the polymer chains.

A TFCL according to the present invention containing the effect pigment may also be a glass, enamel or ceramic layer. Thus, in another preferred embodiment at least one, preferably exactly one, of the TFCLs is a glass, enamel or ceramic layer, while the other TFCLs are selected from polymer films or sheets. For example, according to this preferred embodiment it is possible to provide a first TFCL which is a glass, enamel or ceramic layer containing a first effect pigment, for example silver white or another color, and laminate onto it a second TFCLs containing a second effect pigment and optionally further TFCLs each containing an effect pigment, wherein these second and further TFCLs are polymer films and the second and further effect pigments are for example selected from yellow, red, green and blue effect pigments.

Generally, however, the use of polymer films as TFCLs is more preferred, in order to make best use of the advantageous effects as described above which are related to flexibility and reproducibility when providing customized colors at large scale.

If a TFCL containing the effect pigment is a glass, enamel or ceramic layer, its thickness is preferably 5 μm to 200 μm, very preferably 10 μm to 100 μm, most preferably 15 μm to 70 μm.

A TFCL which is a glass layer can be prepared for example by mixing the effect pigment(s) and optional additives with glass frits or flux, ceramic or enamel precursor(s), placing the mixture onto a substrate and baking or firing the mixture at a temperature above the glass temperature of the glass frits, flux, ceramic or enamel, respectively. Typical application methods of the precursor composition to the substrate include roller coating, screen printing or spraying of a mixture of flux, enamel or ceramic precursors, pigments and optionally other additives in solvent e.g. water or glycol ether.

Especially in the decoration of glass articles, in particular glass plates, preferably a precursor composition is used which contains one or more pigments, optionally one or more additives, and one or more glass frits or flux. The precursor composition is baked after coating onto the substrate, whereby a glass-enamel containing the pigments and optional additives is formed. In the application of the precursor composition onto glass plates, the melt behaviour of the precursor composition should be adjusted according to typical conditions of the tempering process. Typical baking conditions are glass temperatures between approximately 580° C. and 650° C. and baking times of a few minutes. For colourful decoration of glass plates in architectural and instrument glass areas a good compatibility is required between the glass frit contained in the compositions with the inorganic pigments. The requirements of the baked compositions, i.e. of the glass-enamel, in many areas of use include a smooth run with short baking times at as low a temperature as possible, avoidance of cracks, good chemical resistance against acids and alkaline materials as well as good resistance to weathering. Preferred flux are Cadmium and Lead free flux with Si, Zn and B as main components e.g. based on borosilicate glass.

The TFCL according to the invention does also allow to provide color shades or color patterns, such as for mimicking brick walls, which can be achieved e.g. by screen printing two different colors in the desired pattern, or color shades of different surfaces of material used in construction of houses, which can be achieved e.g. by spraying two different color shades into each other.

Impacts of pigments and layers onto c-Si solar cells can be assessed by reflection data. Reflection data are used to estimate max. power absorption/max. photo current generation of treated cells. Reflection and transmission measurements and calculations are conducted by common methods known to the person skilled in the art and as described further in the experimental section.

The transmission of an individual TFCL containing the effect pigments is preferably ≥50%, more preferably ≥70%, very preferably ≥80% for light in the range from 500 to 800 nm, more preferably in the range from 400 to 1000 nm, most preferably in the range from 300 to 1150 nm.

The reflectance of an individual TFCL containing the effect pigment preferably ≤50%, more preferably ≤30%, very preferably from 1 to 20%, for light having a wavelength from 500 to 800 nm, more preferably in the range from 400 to 1000 nm, most preferably in the range from 300 to 1150 nm. A color can already be seen at low reflectance values of 1-5%.

A preferred colored solar cell or colored solar cell module comprising the following components:
two or more TFCLs containing an effect pigment as described above and below,
optionally one or more further transparent layers at the front side of the solar cell,
one or more solar cells, or an array of solar cells which are electrically interconnected by conducting parts, preferably by bus bars,
optionally a rear encapsulant sheet,
a rear sheet.

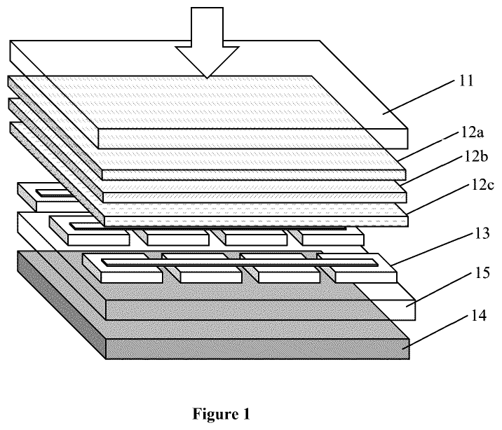

A colored solar cell module according to the present invention is exemplarily and schematically illustrated in FIG. 1 and includes a front sheet (11), three TFCLs (12a,b,c) each containing a different effect pigment, which may also serve as front encapsulant sheets, a pattern or array of solar cells with bus bars (13), an optional rear encapsulant sheet (14), and a rear sheet (15). The arrow indicates the direction of the incident light.

The number of the pigment-containing TFCLs (12a,b,c) can also be changed for example to two, four, five or six individual layers. The TFCLs can also be laminated and pressed together under heat, optionally with the transparent front sheet (11), to from a monolithic multilayer.

In another preferred embodiment (not shown in FIG. 1), one or more front encapsulant films (16) are provided between the front sheet (11) and the pigment containing layers (12a,b,c) or between the pigment containing layers (12a,b,c) and the solar cells (13). The front encapsulant film(s) (16) do not contain effect pigments.

In another preferred embodiment (not shown in FIG. 1), the solar cell module does not contain the front sheet (11), and the TFCLs (12a,b,c) containing the effect pigments are serving as front sheet.

In another preferred embodiment (not shown in FIG. 1), one or more of the TFCLs (12a,b,c), preferably the outermost TFCL (12a), are serving as front encapsulant sheet(s).

In another preferred embodiment (not shown in FIG. 1), a protective foil or an exterior foil is applied on top of the finished solar cell or solar cell module.

The TFCLs (12a,b,c) are located at the radiation-receiving side, i.e. within the visible parts of the solar cells or solar cell modules according to the present invention. They may be located in the solar cell module on the inside of the front sheet (11), i.e. the side facing the solar cell or array of solar cells, as shown in FIG. 1, or alternatively they may be located on the outside of the front sheet (11), i.e. the side facing the incident light.

The TFCLs (12a,b,c) can be locally and flexibly applied on any surface. Thus, they can be applied on the exterior of a finished solar cell or solar cell module, on the protective substrate covering the solar cell or solar cell module (glass or plastic), or directly on the photoactive material/solar cells.

Advantageously, the TFCLs (12a,b,c) can also be used as anti-reflective film.

Generally, the components located at the front side of the solar cell module, like the front sheet (11), the TFCLs (12a,b,c) and optional further front encapsulant films are substantially transparent to incident light passing through to the solar cell or solar cell array (13).

If one or more of the layers or sheets at the front and rear side (11, 12a,b,c, 14, 15, 16) are polymer films, they are preferably selected from organic polymers including but not limited to polyolefins like for example polyethylene polymers or copolymers such as polyethylene, EVA (ethylene vinylacetate), EBA (ethylene butylacrylate), EMA (ethylene methylacrylate), EEA (ethylene ethylacrylate), POE (polyolefin elastomer), BPO, furthermore polyesters, polyamides, polyurethanes, polyvinylbutyral PVB, polycarbonates, polyvinylchloride, polyvinyl acetate, polyacrylates, polyols, polyisocyanates or polyamines, as well as copolymers, resins, blends or multilayers of the aforementioned, such as polycarbonate-containing urethane resins, vinyl chloride-vinyl acetate containing urethane resins, acrylic resins, polyurethane acrylate resins, polyester resins, or TPU (thermoplastic polyurethane), very preferably TPU or a polyolefin including but not limited to EVA, EBA, EMA, EEA, POE or BPO, most preferably EVA.

The TFCLs (12a,b,c), the optional front encapsulant sheet (16) and the optional rear encapsulant sheet (14) are preferably selected from polyolefin polymer or copolymer films, very preferably from polyethylene polymer or copolymer films, in particular from EVA, EBA, EMA, EEA, POE, BPO, PVB or TPU films, most preferably from polyethylene copolymer or EVA films.

The front sheet (11) and rear sheet (15) are preferably selected from glass sheets. In another preferred embodiment, the front sheet (11) and/or the rear sheet (14), more preferably the rear sheet (15), is a polymer sheet, for example a TPT or polycarbonate sheet.

Further preferred polymers for use as or in rear sheets (15) can be categorized into double fluoropolymers, single fluoropolymers and non-fluoropolymers and various constructions within each category. Double fluoropolymer rear sheets do typically consist mainly of outer layers of Tedlar® polyvinyl fluoride (PVF) films, or Kynar® polyvinylidene fluoride (PVDF) films, and a core layer of polyethylene terephthalate (PET). Single fluoropolymer rear sheets do typically consist of Tedlar or Kynar® on the air side and PET and primer or EVA layers on the inner side. Non-fluoropolymer rear sheets do typically consist of two PET and one primer or EVA layers.

In a preferred embodiment of the present invention, the rear sheet (15) is black or of a dark color like dark blue, and/or a black or dark colored sheet, for example a rear encapsulant sheet (14), is provided at the rear side of the solar cell or solar cell module, i.e. between the solar cells (13) and the rear sheet (15), wherein the dark color is preferably a dark blue equal to the color of solar cells.

The solar cell array (13) as exemplarily shown in FIG. 1 may also be replaced by a single solar cell.

The colored solar cell or colored solar cell module according to the present invention and the solar cells (13) in FIG. 1 can be selected from any type of device collecting and converting solar energy, such as solar thermal or photovoltaic device, including but not limited to organic photodiodes, solar cells or solar cell modules, which can be organic, inorganic or hybrid types, including but not limited to amorphous, mono- and multi crystalline silicon solar cells, CIGS, CdTe, III/V solar cells, II/VI solar cells, perovskite solar cells, organic solar cells, quantum dot solar cells and dye sensitized solar cells, as well as solar cell modules made out of single cells. Crystalline solar cells include cell structures like Al-BSF, PERC, PERL, PERT, HIT, IBC, bifacial or any other cell type based on crystalline silicon substrates.

The colored solar cell or colored solar cell module according to the present invention and the solar cells (13) in FIG. 1 can also be selected from devices collecting and converting solar energy such as solar thermal devices or photodiodes.

In the solar cells (13) the conducting parts preferably comprise metal based conducting parts including but not limited to the following parts:
i) the H-grid consisting of main vertical connectors-so called bus bars,
ii) the horizontal current gathering parts-so called fingers,
iii) connectors and solder between the cells,
In a preferred embodiment of the invention, in order to achieve a fully homogeneous appearance of the solar cells (13) the metal based conducting parts, including but not limited to the aforementioned parts i) to iii), are preferably colored black or in a dark color like dark solar blue prior to the application of the layer (12) with the effect pigments and the light scattering centers.

In another preferred embodiment of the invention, a grid of dark color, preferably black or dark blue, is incorporated into one or more layers of the solar cells, said grid covering bright areas like the space between the single solar cells and the conducting parts including bus bars, conducting path and soldering points. In another preferred embodiment of the invention, to hide the space between the single solar cells, a black or dark blue back layer is applied behind the solar cells. The black or dark blue back layer can be printed or applied as a foil.

Suitable and preferred ways of darkening the else white appearing metal parts of the solar cells (13) with a H-grid front pattern include covering the metal stripes with a black polymer foil or brushing the metal parts with a black paint. In the case of a printed silver H-grid the silver can directly be blackened by formation of a thin layer of silver-sulphide (for example by treatment with H₂S) or by plating and oxidation of copper. In the case of a plated metal grid the top layer of the metal stack can directly be plated with a strongly absorbing metal oxide or sulphide like CuO or Ag₂S or similar dark colored metal oxides or others. In the case of the usage of novel metallization schemes (like the smart wire technology) blackened wires or wires with a microstructure reducing the reflectance and thus making a dark appearance of the metal grid can also be used according to the invention. If a black or dark solar blue rear sheet is used as module background, a very homogeneous appearance of the whole module even from a close distance can be achieved.

The colored solar cells and colored solar cell modules according to the present invention can be manufactured by methods and means known to the person skilled in the art and described in the literature.

For example, the existing state of the art techniques for manufacturing encapsulated solar cell modules do typically include to build a stack of front glass and solar cells mounted with bus bars embedded in encapsulant films laminated to a back sheet or glass. The stack is then heated up e.g. to 130° C. to 160° C. (depending on the type of encapsulant material used) and pressed together by vacuum or any other type of physical pressure.

Preferably, the TFCLs with the effect pigment and the other individual components or layers of the solar cell module as described above and below are stacked in the desired sequence and then laminated together e.g. by applying heat and/or pressure, or using an adhesive or a binding agent.

Alternatively the lamination process of preparing the solar cell module or solar cell modules can also be carried out in two steps, such that the layer containing the effect pigments is laminated to the front sheet in a first lamination (or pre-lamination) step, and then the front sheet plus the laminated layer containing the effect pigments and is laminated to the stack of the remaining components in a second lamination step.

A preferred process for preparing a colored solar cell or colored solar cell module according to the present invention comprises the steps of laminating two or more TFCLs containing an effect pigment as described above and below to the front side of a solar cell or a solar cell module, wherein the effect pigments in at least two of the TFCLs have different color.

The lamination steps, can be carried out by using standard methods, e.g. subjecting the two layers to heat and pressure, e.g. by applying a vacuum and/or any other form of physical pressure, for a certain time interval, e.g. in a lamination machine.

Alternatively and/or additionally lamination can be achieved or supported by using one or more adhesives and/or bonding agents or layers. Adhesives/bonding agents can be reactive or non-reactive and can comprise or consist of natural, or synthetic origin. Suitable and preferred examples include, without limitation, polyurethane (PUR), thermoplastic polyurethane (TPU), rubber, acrylic and silicone adhesives, depending on the desired application.

In the lamination steps, the suitable applied heat and pressure and the time interval depend on the type of sheets and films used and can be easily chosen by the person skilled in the art. In case a front glass sheet and a polymer film of EVA are used, preferably the heating temperature is in the range of 130° C. to 160° C., very preferably ca. 135° C., and the time interval is preferably 20 to 30 minutes. Preferably a vacuum press is used. Preferably a pressure of 400 to 900 mbar is applied.

After the final lamination step the laminated stack is cooled down, preferably to room temperature. Excessive material of the encapsulant films and rear sheets (in case a plastic rear sheet is used) can be cut away and a junction box can be attached for electrical connection of the solar cell module. Finally the laminate can be framed.

After the lamination step(s) the film thickness will usually be reduced depending on the lamination conditions.

Preferably the resulting laminate is completely sealed and, in the ideal case, can protect the solar cells for at least 25 years.

Preferably the solar cells and solar cell modules according to the present invention show a power change ΔP of >−20%, more preferably >−10%, very preferably >−6%, wherein

$$Δ P ( \% ) = \frac{{P}_{i} - {P}_{ref}}{{P}_{ref}} \times 100$$

and Pᵢ is the power of a solar cell or solar cell module SCᵢ according to the present invention with a layer containing the effect pigments and scattering centers as described above and below, and Pref is the power of a reference solar cell or solar cell module SC_{ref} having the same components as SCᵢ except that the layer with the effect pigments does not contain optional additives. A negative value of ΔP thus indicates a power loss and a positive value of ΔP indicates a power gain vs. the reference.

The following examples are intended to explain the present invention without restricting it.

### Example 1—Stack of Colored Polymer Films

Different polyethylene films according to the invention were prepared containing 0.15% of an effect pigment, resulting in an effect pigment concentration of ca. 1 g/m².

While encapsulant films are usually prepared via extrusion of casts films, for practical reasons in the present examples film samples with a size 10×15 cm and a thickness of 700 μm were prepared via injection moulding of a polyethylene resin containing the pigment and the particles as follows:

An injection-moulding machine of the Kraus-Maffei CX-130-380 type was used. After closing of the mould, a transparent plastic melt (Evatane® 28-25PV, product from Arkema) was injected into the injection mould. The injection operation was carried out at a temperature in the range from 180 to 200° C. and a pressure in the range from 450 to 900 bar (4.5×10⁷ N/m² to 9×10⁷ N/m²). For coloring the plastic melt or adding the scattering particles, a masterbatch was used accordingly in the required concentration. The polymer film can be embossed in a post-step when needed. Embossing structure usually support removal of air during lamination step of solar modules.

On a glass sheet of 6×12 cm a black EVA film is placed with a size of 10×6 cm to leave some part of the glass uncovered. On top of the black EVA film an EVA film containing a red effect pigment (Pyrisma® T30-21 Color Space Red), an EVA film containing a green effect pigment (Pyrisma® T30-24 Color Space Green) and an EVA film containing a blue effect pigment (Pyrisma® T30-23 Color Space Blue) are placed, each film having a thickness of 450 μm (450 g/m²) and a size of 6×12 cm. The red, green and blue effect pigments are interference pigments consisting of a natural mica substrate with a TiO₂ coating. On top of this a second glass sheet of 6×12 cm is placed. Then the stack is placed in a vacuum bag into an oven. The stack is treated with 70 kPa at 150° C. for 10 minutes. After cooling down the sample is removed out of the vacuum bag.

A multilayer film of grey color is achieved. Transmission measurements are carried out at the parts where no black EVA is placed. The transmission is compared against a non-colored standard laminated stack, and shows only a transmission reduction of less than 20% caused by the effect pigments.

### Example 1—Stack of Colored Polymer Films and Colored Glass

### Film Preparation

A EVA film is prepared containing 0.15% of the effect pigment Pyrisma® T30-24 Color Space Green, resulting in a concentration of 1 g/m² of effect pigment at a film thickness of 450 μm.

### Colored Glass Front Sheet Preparation

A layer containing the effect pigment Pyrisma® T30-23 Color Space Blue in a water based glass/frits mixture is directly printed on commercially available glass used for solar modules with state of the art screen printing resulting in a wet layer of 35-40 μm. The printed glass is tempered at 600° C.-680° C. in an oven resulting in a dry layer of glass-enamel with a thickness of 20-25 μm and 1 g/m² effect pigment.

### Sample Preparation

A sample is prepared forming the following layers:
Non colored glass 10 cm×10 cm and 2 mm thickness
Black EVA film 10 cm×5 cm
10 cm×10 cm colored encapsulant EVA film (450 μm) colored with 1 g/m² Pyrisma® T30-24 Color Space Green
Colored Glass 10 cm×10 cm and 2 mm thickness, colored with 1 g/m² Pyrisma® T30-23 Color Space Blue
Treatment of the stack of layers in a vacuum bag at −70 kPa and 150° C. for 10 minutes in a drying closet

After cooling down the sample is removed out of the vacuum bag. A multilayer with a turquoise color is achieved.

Transmission measurements are carried out at the parts where no black EVA film is placed. The transmission is compared against a non-colored standard laminated stack, and shows only a transmission reduction of less than 20% caused by the effect pigments.

1. A colored solar cell or colored solar cell module comprising two or more transparent front cover layers, each of said transparent front cover layers containing at least one effect pigment that has a specific color and consists of a transparent or semi-transparent flake-form substrate coated with one or more layers of transparent or semi-transparent materials and optionally a post coating, wherein at least one of the transparent front cover layers contains an effect pigment having a different color than the effect pigment(s) contained in the other transparent front cover layer(s).

2. The colored solar cell or colored solar cell module according to claim 1, wherein transparent front cover layers are selected from polymer films or sheets.

3. The colored solar cell or colored solar cell module according to claim 1, wherein the transparent front cover layers are selected from EVA, EBA, EMA, EEA, POE, PC, BPO, PVB or TPU films.

4. The colored solar cell or colored solar cell module according to claim 1, wherein the transparent front cover layers are encapsulant films or a component thereof or together form an encapsulant film or a component thereof.

5. The colored solar cell or colored solar cell module according to claim 1, comprising two or more transparent cover layers at least one of which contains an effect pigment having a different color than the effect pigment(s) contained in the other transparent front cover layer(s).

6. The colored solar cell or colored solar cell module according to claim 1, comprising two or more transparent front cover layers at least one of which contains an effect pigment that has a different color than the effect pigment(s) contained in the other transparent front cover layer(s) and is selected from silver white, yellow, red, green and blue effect pigments.

7. The colored solar cell or colored solar cell module according to claim 1, wherein the concentration of the effect pigment in each individual transparent front cover layer is from 0.02 to 15% by weight.

8. The colored solar cell or colored solar cell module according to claim 1, wherein each transparent front cover layer has a transmission ≥50% for light having a wavelength from 500 nm to 800 nm.

9. The colored solar cell or colored solar cell module according to claim 1, wherein each individual transparent front cover layer containing the effect pigment has a thickness of 5 μm to 1000 μm.

10. The colored solar cell or colored solar cell module according to of claim 1, wherein the effect pigments are selected from pearlescent pigments, interference pigments and multilayer pigments.

11. The colored solar cell or colored solar cell module according to claim 1, wherein the effect pigments are based on synthetic or natural mica, flake-form glass substrates, flake-form SiO₂ substrates or flake-form Al₂O₃ substrates.

12. The colored solar cell or colored solar cell module according to claim 11, wherein the flake-form substrate is coated with one or more layers of metal oxides and/or metal oxide hydrates of Ti, Sn, Si, Al, Zr, Fe, Cr or Zn.

13. A colored solar cell or colored solar cell module comprising the following components:
two or more transparent front cover layers, each of said transparent front cover layers containing at least one effect pigment that has a specific color and consists of a transparent or semi-transparent flake-form substrate coated with one or more layers of transparent or semi-transparent materials and optionally a post coating, wherein at least one of the transparent front cover layers contains an effect pigment having a different color than the effect pigment(s) contained in the other transparent front cover layer(s),
optionally one or more further transparent layers at the front side of the solar cell,
one or more solar cells, or an array of solar cells which are electrically interconnected by conducting parts, preferably by bus bars,
optionally a rear encapsulant sheet,
a rear sheet.

14. The colored solar cell or colored solar cell module according to claim 13, wherein the rear sheet is black or has dark color, and/or the colored solar cell or colored solar cell module comprises an additional sheet or an encapsulant film provided between the solar cell(s) or solar cell array and the rear sheet, wherein said additional sheet or encapsulant film is black or has dark color.

15. A process for preparing a colored solar cell or colored solar cell module, comprising the steps of laminating two or more transparent front cover layers, each of said transparent front cover layers containing at least one effect pigment that has a specific color and consists of a transparent or semi-transparent flake-form substrate coated with one or more layers of transparent or semi-transparent materials and optionally a post coating, to a front side of a solar cell or a solar cell module, wherein at least one of the transparent front cover layers contains an effect pigment having a different color than the effect pigment(s) contained in the other transparent front cover layer(s).

16. The process according to claim 15, wherein the lamination steps are carried out by applying heat and/or pressure, or using an adhesive or a binding agent or layer.

17. An architectural installation or a device comprising one or more colored solar cells or colored solar cell modules according to claim 1, which is selected from the group consisting of windows, doors, building façades, building roofs or floors, walls, structural glass, curtain walls, showrooms, car roofs, car bodies, mobile phones, hand-held PC's such as tablets, plug-in solar modules, roof tiles, solar panels, PV fences, military devices, radio sets, radio equipment, music boxes, power banks, watches, eyeglasses and goggles.
